(19) United States
(12) Patent Application Publication
(10) Pub. No.: US 2025/0089517 A1
(43) Pub. Date: Mar. 13, 2025

(54) GUIDE FILM, APPARATUS FOR MANUFACTURING DISPLAY DEVICE, AND METHOD OF MANUFACTURING DISPLAY DEVICE

(71) Applicant: SAMSUNG DISPLAY CO., LTD., YONGIN-SI (KR)

(72) Inventors: SOYEON EOM, Yongin-si (KR); SEHUN PARK, Yongin-si (KR)

(21) Appl. No.: 18/752,933

(22) Filed: Jun. 25, 2024

(30) Foreign Application Priority Data
Sep. 11, 2023 (KR) 10-2023-0120740

(51) Int. Cl. H10K 59/80; H10K 59/12; H10K 71/50

(52) U.S. Cl. CPC H10K 59/80; H10K 59/1201; H10K 71/50

(57) ABSTRACT

A guide film includes a base film including a main area, which includes a first side extending in a first direction and a second side contacting the first side and extending in a second direction crossing the first direction, a first auxiliary area contacting the first side, and a second auxiliary area contacting the second side, and a support member disposed in the base film in the first auxiliary area and the second auxiliary area and including a metal.

### CROSS-REFERENCE TO RELATED APPLICATION

This application claims priority under 35 USC § 119 to Korean Patent Application No. 10-2023-0120740, filed on Sep. 11, 2023, in the Korean Intellectual Property Office, the content of which is herein incorporated by reference in its entirely.

### BACKGROUND

### 1. Field

The present disclosure relates to a guide film. More particularly, the present disclosure relates to an apparatus, which includes a guide film, for manufacturing display device and a method of manufacturing a display device using the guide film.

### 2. Description of the Related Art

With the development of information technology, the importance of a display device, which is a connection medium between a user and information, has been highlighted. For example, the use of display devices such as liquid crystal display (LCD) device, organic light emitting display (OLED) device, plasma display panel (PDP) device, and quantum dot display device is increasing.

The display device may include a cover window capable of transmitting light and a display panel disposed under the cover window and capable of emitting light. Conventionally, display panels including only flat surfaces have been used, but recently, display panels including various curved surfaces have been used. Typically, the display device may be manufactured by attaching the display panel under the cover window.

### SUMMARY

Embodiments provide a guide film including a support member.

Embodiments provide an apparatus, which includes the guide film, for manufacturing a display device.

Embodiments provide a method of manufacturing a display device with improved attachment between a display panel and a cover window.

A guide film according to an embodiment of the present disclosure includes a base film including a main area, which includes a first side extending in a first direction and a second side contacting the first side and extending in a second direction crossing the first direction, a first auxiliary area contacting the first side, and a second auxiliary area contacting the second side, and a support member disposed in the first auxiliary area and the second auxiliary area of the base film and including a metal.

In an embodiment, the support member may include a plurality of support patterns spaced apart from each other.

In an embodiment, the plurality of support patterns may be arranged in a zigzag shape in a plan view.

In an embodiment, the plurality of support patterns may include a plurality of groups, each of the plurality of groups including at least two support patterns arranged in a straight line extending along the first direction in a plan view. The plurality of groups may be arranged along the second direction.

In an embodiment, the base film may include a plurality of film layers, and the support member is disposed in at least one of the plurality of film layers.

In an embodiment, a rigidity of the support member may be greater than a rigidity of the base film.

In an embodiment, the main area of the base film may include a different material from each of the first auxiliary area and the second auxiliary area of the base film.

An apparatus for manufacturing a display device according to an embodiment of the present disclosure includes a guide film on which a display panel is disposed, a jig on which a cover window is disposed, and a pad part on which the display panel and the guide film are disposed, the pad part facing the jig. The guide film includes a base film on which the display area is disposed and a support member disposed in the base film, overlapping at least a portion of an edge of the display panel in a plan view, and including a metal.

In an embodiment, the support member may include a plurality of support patterns spaced apart from each other.

In an embodiment, the plurality of support patterns may be arranged in a zigzag shape in a plan view.

In an embodiment, the plurality of support patterns may include a plurality of groups, each of the plurality of groups including at least two support patterns arranged in a straight line extending along a first direction in a plan view. The plurality of groups may be arranged along a second direction crossing the first direction.

In an embodiment, a rigidity of the support member may be greater than a rigidity of the base film.

A method for manufacturing a display device according to an embodiment of the present disclosure includes attaching a guide film to a back surface of a display panel, wherein the guide film includes a base film and a support member disposed in the base film, wherein the support member includes a metal, and wherein the support member overlaps at least a portion of an edge of the display panel in a plan view, bending the display panel by applying an external force to the guide film, aligning a front surface of the display panel to face a cover window, and attaching the display panel to the cover window.

In an embodiment, in the bending the display panel, the support member may overlap at least partially a bent portion of the display panel.

In an embodiment, the support member may include a plurality of support patterns spaced apart from each other.

In an embodiment, the attaching the guide film to the back surface of the display panel may include aligning the display panel and the guide film with each other. The aligning the display panel and the guide film each other includes aligning a first alignment mark marked on the display panel to the plurality of support patterns.

In an embodiment, the aligning the front surface of the display panel to the cover window includes aligning a second alignment mark marked on the cover window to the plurality of support patterns.

In an embodiment, the plurality of support patterns may be arranged in a zigzag shape in a plan view.

In an embodiment, the plurality of support patterns may include a plurality of groups, each of the plurality of groups including at least two support patterns arranged in a straight line extending along a first direction in a plan view. The plurality of groups may be arranged along a second direction crossing the first direction.

In an embodiment, a rigidity of the support member may be greater than a rigidity of the base film.

A guide film according to an embodiment of the present disclosure may include a base film and a support member disposed in the base film. The support member may include a metal.

In the process of attaching a display panel and a cover window, the support member may overlap an area where the display panel and the cover window are bent in a plan view. Accordingly, during the process of attaching the display panel and the cover window, components included in the display panel may not be restored to their shape before being bent. That is, the generation of bubbles due to lifting of the cover window in an area where the cover window is bent may be reduced. Accordingly, the display panel and the cover window may be smoothly attached.

The support member may include support patterns spaced apart from each other. The support patterns may serve as alignment marks in the process of attaching the display panel and the guide film. Accordingly, the alignment accuracy between the display panel and the guide film may be relatively increased.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating a display device according to an embodiment of the present disclosure.

FIGS. 2, 3, and 4 are cross-sectional views illustrating the display device of FIG. 1 according to an embodiment of the present disclosure.

FIG. 5 is an enlarged cross-sectional view of area ‘A’ of FIG. 4 according to an embodiment of the present disclosure.

FIG. 6 is a cross-sectional view illustrating an apparatus for manufacturing a display device according to an embodiment of the present disclosure.

FIG. 7 is a plan view illustrating a guide film according to an embodiment of the present disclosure.

FIG. 8 is a cross-sectional view taken along line I-I′ of FIG. 7 according to an embodiment of the present disclosure.

FIG. 9 is an enlarged plan view of area ‘B’ of FIG. 7 according to an embodiment of the present disclosure.

FIG. 10 is a plan view illustrating a guide film according to an embodiment of the present disclosure.

FIG. 11 is a cross-sectional view taken along line II-II′ of FIG. 10 according to an embodiment of the present disclosure.

FIG. 12 is a plan view illustrating a guide film according to an embodiment of the present disclosure.

FIG. 13 is an enlarged plan view of area ‘C’ of FIG. 12 according to an embodiment of the present disclosure.

FIG. 14 is a flowchart illustrating a method for manufacturing a display device according to an embodiment of the present disclosure.

FIGS. 15, 16, 17, 18, 19, 20, 21, 22, and 23 are views illustrating the method of manufacturing the display device of FIG. 14 according to an embodiment of the present disclosure.

### DETAILED DESCRIPTION OF THE EMBODIMENTS

Hereinafter, embodiments of the present disclosure will be described in detail with reference to the accompanying drawings. The same reference numerals are used for the same components in the drawings, and redundant descriptions of the same components will be omitted.

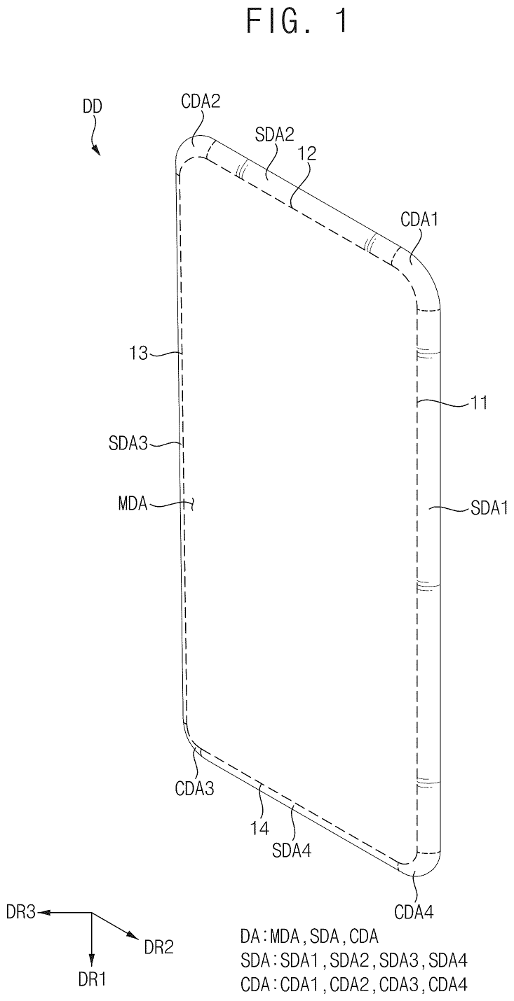

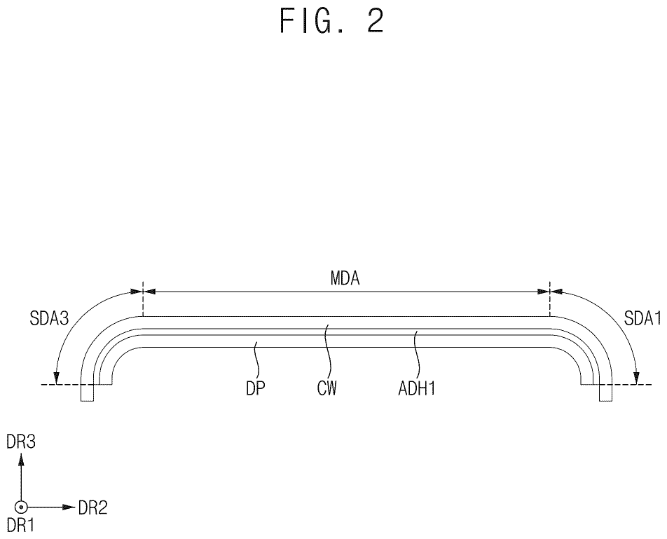

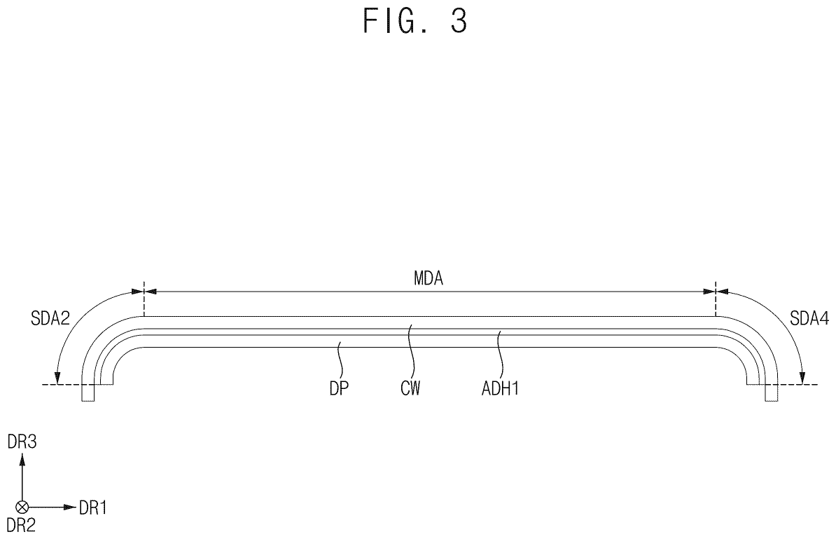

FIG. 1 is a perspective view illustrating a display device according to an embodiment of the present disclosure. FIGS. 2 and 3 are cross-sectional views illustrating the display device of FIG. 1.

In this specification, a plane may be defined by a first direction DR1 and a second direction DR2 crossing the first direction DR1. For example, the first direction DR1 and the second direction DR2 may be perpendicular to each other. A direction normal to the plane, that is, a thickness direction of a display device DD may be a third direction DR3. In other words, the third direction DR3 may be perpendicular to each of the first direction DR1 and the second direction DR2.

Referring to FIGS. 1, 2, and 3, the display device DD according to an embodiment of the present disclosure may include a display panel DP and a cover window CW.

The display panel DP may be disposed under the cover window CW. The display panel DP may be attached to the cover window CW by a first adhesive layer ADH1. The first adhesive layer ADH1 may include a transparent adhesive, such as a pressure sensitive adhesive (PSA) film, an optically clear adhesive (OCA) film, and an optically clear adhesive resin (OCR). The first adhesive layer ADH1 may be formed on the display panel DP by various methods, such as being formed in the form of a film and attached on the display panel DP, or in the form of a material and coated on the display panel DP.

The display panel DP may include a display area DA capable of displaying an image. That is, the display area DA may be defined as an area that displays an image by generating light or adjusting the transmittance of light provided from an external light source. A plurality of pixels may be disposed in the display area DA. The pixels may generate light according to a driving signal. The pixels may be repeatedly disposed along the first direction DR1 and the second direction DR2. Data lines, gate lines, and light emitting control lines connected to the pixels may be further disposed in the display area DA.

The display area DA may include a main display area MDA, a side display area SDA, and a corner display area CDA. The pixels disposed in each of the main display area MDA, the side display area SDA, and the corner display area CDA may display an image.

The main display area MDA may include a flat surface. For example, the main display area MDA may have a square shape with rounded corners in a plan view. However, the present disclosure is not limited thereto.

The main display area MDA may include a first side 11, a second side 12, a third side 13, and a fourth side 14. The first side 11 and the third side 13 may face each other and extend in parallel along the first direction DR1. Each of the second side 12 and the fourth side 14 may be in contact with the first side 11 and the third side 13. The second side 12 and the fourth side 14 may face each other and extend in parallel along the second direction DR2. In an embodiment, a length of the first side 11 may be greater than a length of the second side 12. That is, the main display area MDA may have a rectangular shape with rounded corners in a plan view, with the first side 11 as a long side and the second side 12 as a short side. However, the present disclosure is not limited thereto.

The side display area SDA may include a first side display area SDA1, a second side display area SDA2, a third side display area SDA3, and a fourth side display area SDA4.

The first side display area SDA1, the second side display area SDA2, the third side display area SDA3, and the fourth side display area SDA4 may be in contact with the first side 11, the second side 12, the third side 13, and the fourth side 14 of the main display area MDA, respectively. That is, the first side display area SDA1 may be in contact with the first side 11 and may be adjacent to the main display area MDA in the second direction DR2. The second side display area SDA2 may be in contact with the second side 12 and may be adjacent to the main display area MDA in the first direction DR1. The third side display area SDA3 may be in contact with the third side 13 and may be adjacent to the main display area MDA in the second direction DR2. The fourth side display area SDA4 may be in contact with the fourth side 14 and may be adjacent to the main display area MDA in the first direction DR1.

As illustrated in FIGS. 2 and 3, the display panel DP may be bent in a direction opposite to the third direction DR3 in the first to fourth side display areas SDA1, SDA2, SDA3, and SDA4. That is, the display panel DP may be at least partially bent in the first to fourth side display areas SDA1, SDA2, SDA3, and SDA4. In other words, the display panel DP may include a curved surface in the first to fourth side display areas SDA1, SDA2, SDA3, and SDA4.

The corner display area CDA may include a first corner display area CDA1, a second corner display area CDA2, a third corner display area CDA3, and a fourth corner display area CDA4.

The first corner display area CDA1 may be positioned between the first side display area SDA1 and the second side display area SDA2. That is, the first corner display area CDA1 may connect the first side display area SDA1 to the second side display area SDA2. The second corner display area CDA2 may be positioned between the second side display area SDA2 and the third side display area SDA3. That is, the second corner display area CDA2 may connect the second side display area SDA2 to the third side display area SDA3. The third corner display area CDA3 may be positioned between the third side display area SDA3 and the fourth side display area SDA4. That is, the third corner display area CDA3 may connect the third side display area SDA3 to the fourth side display area SDA4. The fourth corner display area CDA4 may be positioned between the first side display area SDA1 and the fourth side display area SDA4. That is, the fourth corner display area CDA4 may connect the first side display area SDA1 to the fourth side display area SDA4.

The display panel DP may be bent in the direction opposite to the third direction DR3 in the first to fourth corner display areas CDA1, CDA2, CDA3, and CDA4. That is, the display panel DP may be at least partially bent in the first to fourth corner display areas CDA1, CDA2, CDA3, and CDA4. In other words, the display panel DP may include a curved surface in the first to fourth corner display areas CDA1, CDA2, CDA3, and CDA4.

The cover window CW may be disposed on the display panel DP. The cover window CW may cover and protect the display panel DP. The cover window CW may include a transparent material. In an embodiment, the cover window CW may include a flexible material. The flexible material may refer to a material that is flexible and can be easily bent, folded, or rolled. For example, the cover window CW may include ultrathin type glass or plastic. In an embodiment, the cover window CW may be a flexible, transparent material such as ultrathin glass and plastic.

The cover window CW may be bent in the direction opposite to the third direction DR3 in areas overlapping the first to fourth side display areas SDA1, SDA2, SDA3, and SDA4. That is, the cover window CW may be at least partially bent in the areas overlapping the first to fourth side display areas SDA1, SDA2, SDA3, and SDA4.

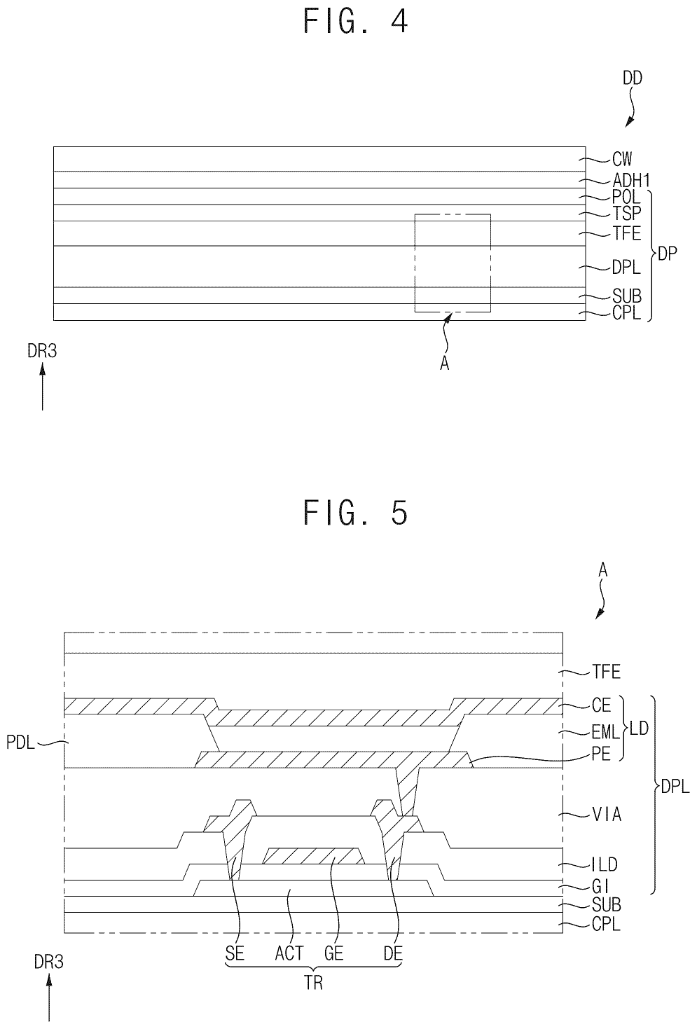

FIG. 4 is a cross-sectional view illustrating the display device of FIG. 1. FIG. 5 is an enlarged cross-sectional view of area ‘A’ of FIG. 4.

Referring to FIGS. 4 and 5, the display device DD according to an embodiment of the present disclosure may include the cover window CW and the display panel DP. The display panel DP may be attached to the cover window CW by the first adhesive layer ADH1. The display panel DP may include a substrate SUB, a display layer DPL, an encapsulation layer TFE, a touch sensing layer TSP, an anti-reflection layer POL, and a cover panel CPL.

The substrate SUB may include a transparent material or an opaque material. The substrate SUB may be formed of a transparent resin substrate. A polyimide substrate may be an example of the transparent resin substrate. In this case, the polyimide substrate may include a first organic layer, a first barrier layer, a second organic layer, etc. In an embodiment, the substrate SUB may include a quartz substrate, a synthetic quartz substrate, a calcium fluoride substrate, a fluorine-doped quartz substrate, a soda-lime glass substrate, a non-alkali glass substrate, etc. These may be used alone or in combination with each other.

The cover panel CPL may be disposed under the substrate SUB. The cover panel CPL may protect the substrate SUB from external impacts. In addition, the cover panel CPL may prevent scratches on a back surface of other components of the display panel DP during the manufacturing process of the display panel DP.

The display layer DPL may be disposed on the substrate SUB. As illustrated in FIG. 5, the display layer DPL may include a thin film transistor TR, a gate insulating layer GI, an inter-layer insulating layer ILD, a via-insulating layer VIA, a light emitting element LD, and a pixel defining layer PDL. The thin film transistor TR may include an active layer ACT, a gate electrode GE, a source electrode SE, and a drain electrode DE. The light emitting element LD may include a pixel electrode PE, a light emitting layer EML, and a common electrode CE.

A buffer layer may be disposed on the substrate SUB. The buffer layer may prevent diffusion of metal atoms or impurities from the substrate SUB to an upper structure (e.g., the thin film transistor TR, the light emitting element LD, etc.). In addition, the buffer layer may obtain the substantially uniform active layer ACT by controlling a heat transfer rate during a crystallization process for forming the active layer ACT. For example, the buffer layer may include inorganic insulating material. In an embodiment, the buffer layer may be omitted.

The active layer ACT may be disposed on the substrate SUB. The active layer ACT may include an oxide semiconductor, a silicon semiconductor, an organic semiconductor, etc. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), etc. These may be used alone or in combination with each other. The silicon semiconductor may include amorphous silicon, polycrystalline silicon, etc. The active layer ACT may include a source area, a drain area, and a channel area positioned between the source area and the drain area.

The gate insulating layer GI may be disposed on the active layer ACT and the substrate SUB. The gate insulating layer GI may cover the active layer ACT on the substrate SUB and may be disposed along the profile of the active layer ACT with a substantially uniform thickness. For example, the gate insulating layer GI may be conformally formed on the active layer ACT. In an embodiment, the gate insulating layer GI may sufficiently cover the active layer ACT on the substrate SUB, and may have a substantially flat upper surface without creating a step difference around the active layer ACT. The gate insulating layer GI may include an inorganic insulating material. Examples of the inorganic insulating material that may be used as the gate insulating layer GI may include silicon oxide (SiOx), silicon nitride (SiNx), silicon oxynitride (SiOₓN_{y}), etc. These may be used alone or in combination with each other. The gate insulating layer GI may electrically insulate the active layer ACT from the gate electrode GE.

The gate electrode GE may be disposed on the gate insulating layer GI. The gate electrode GE may overlap the active layer ACT in a plan view. The gate electrode GE may include a metal, an alloy, a metal nitride, a conductive metal oxide, a transparent conductive material, etc. Examples of material that may be used as the gate electrode GE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These may be used alone or in combination with each other.

The inter-layer insulating layer ILD may be disposed on the gate electrode GE and the gate insulating layer GI. The inter-layer insulating layer ILD may cover the gate electrode GE on the gate insulating layer GI and may be disposed along the profile of the gate electrode GE with a substantially uniform thickness. For example, the inter-layer insulating layer ILD may be conformally formed on the gate electrode GE. In an embodiment, the inter-layer insulating layer ILD may sufficiently cover the gate electrode GE on the gate insulating layer GI, and may have a substantially flat upper surface without creating a step difference around the gate electrode GE. The inter-layer insulating layer ILD may include an inorganic insulating material. Examples of the inorganic insulating material that may be used as the inter-layer insulating layer ILD may include silicon oxide (SiOx), silicon nitride (SiNx), silicon oxynitride (SiOxNy), etc. These may be used alone or in combination with each other. The inter-layer insulating layer ILD may electrically insulate the gate electrode GE from the source electrode SE. In addition, the inter-layer insulating layer ILD may electrically insulate the gate electrode GE from the drain electrode DE.

The source electrode SE and the drain electrode DE may be disposed on the inter-layer insulating layer ILD. Each of the source electrode SE and the drain electrode DE may be electrically connected to the active layer ACT through a contact hole penetrating the gate insulating layer GI and the inter-layer insulating layer ILD. Each of the source electrode SE and the drain electrode DE may include a metal, an alloy, a metal nitride, a conductive metal oxide, a transparent conductive material, etc. These may be used alone or in combination with each other.

Accordingly, the thin film transistor TR including the active layer ACT, the gate electrode GE, the source electrode SE, and the drain electrode DE may be formed.

The via-insulating layer VIA may be disposed on the inter-layer insulating layer ILD. For example, the via-insulating layer VIA may be disposed on the inter-layer insulating layer ILD with a relatively thick thickness to sufficiently cover the source electrode SE and the drain electrode DE. The via-insulating layer VIA may include an organic insulating material. Examples of the organic insulating material that may be used as the via-insulating layer VIA may include photoresist, polyacryl-based resin, polyimide-based resin, polyamide-based resin, siloxane-based resin, acryl-based resin, epoxy-based resin, etc. These may be used alone or in combination with each other.

The pixel electrode PE may be disposed on the via-insulating layer VIA. The pixel electrode PE may be electrically connected to the drain electrode DE through a contact hole penetrating the via-insulating layer VIA. Accordingly, the pixel electrode PE may be electrically connected to the thin film transistor TR. For example, the pixel electrode PE may be a semi-transmissive electrode, a transmissive electrode, or a reflective electrode. The pixel electrode PE may include a metal, an alloy, a metal nitride, a conductive metal oxide, a transparent conductive material, etc. These may be used alone or in combination with each other. For example, the pixel electrode PE may serve as an anode electrode.

The pixel defining layer PDL may be disposed on the via-insulating layer VIA. The pixel defining layer PDL may cover an edge of the pixel electrode PE and may expose a portion of an upper surface of the pixel electrode PE. The pixel defining layer PDL may include an organic insulating material. Examples of the organic insulating material that may be used as the pixel defining layer PDL may include photoresist, polyacryl-based resin, polyimide-based resin, polyamide-based resin, siloxane-based resin, acryl-based resin, epoxy-based resin, etc. These may be used alone or in combination with each other.

The light emitting layer EML may be disposed on the pixel electrode PE. The light emitting layer EML may emit light having a specific color (e.g., red, green and/or blue). In an embodiment, the light emitting layer EML may include one or both of an organic light emitting material and a quantum dot. For example, the light emitting layer EML may include an organic material including a fluorescent or phosphorescent material that emits red, green, blue, or white light. The quantum dot may be a particle having a crystal structure of several to tens of nanometers in size, and may include hundreds to thousands of atoms. The quantum dot may include a fluorescent material or a phosphorescent material, and may produce monochromatic red, green, and blue light.

The common electrode CE may be disposed on the pixel defining layer PDL and the light emitting layer EML. Specifically, the common electrode CE may be disposed along the profiles of the pixel defining layer PDL and the light emitting layer EML with a substantially uniform thickness. For example, the common electrode CE may be conformally formed on the pixel defining layer PDL and the light emitting layer EML. In an embodiment, the common electrode CE may include a metal, an alloy, a metal nitride, a conductive metal oxide, a transparent conductive material, etc. These may be used alone or in combination with each other. For example, the common electrode CE may serve as a cathode electrode.

Accordingly, the light emitting element LD including the pixel electrode PE, the light emitting layer EML, and the common electrode CE may be formed.

The encapsulation layer TFE may be disposed on the common electrode CE. The encapsulation layer TFE may prevent impurities, moisture, etc. from penetrating into the light emitting element LD from the outside. The encapsulation layer TFE may include at least one inorganic encapsulation layer and at least one organic encapsulation layer. For example, the inorganic encapsulation layer may include silicon oxide (SiOx), silicon nitride (SiNx), silicon oxynitride (SiOₓN_{y}), etc., and the organic encapsulation layer may include a cured polymer such as polyacrylate.

As illustrated in FIG. 4, the touch sensing layer TSP may be disposed on the encapsulation layer TFE. The touch sensing layer TSP may include a plurality of sensing electrodes and may sense a user's touch. For example, the touch sensing layer TSP may obtain coordinate information according to an external input, for example, the user's touch. The touch sensing layer TSP may detect the external input by using a mutual capacitance method and/or a self-capacitance method. For example, the touch sensing layer TSP may obtain information on the external input through a change in capacitance between two sensing electrodes.

The anti-reflection layer POL may be disposed on the touch sensing layer TSP. External light may enter the display device DD, and the external light may be reflected from various electrodes or lines included in the display layer DPL. The anti-reflection layer POL may prevent the reflected external light from being recognized to the user. The anti-reflection layer POL may include a polarizer and a phase retarder. The anti-reflection layer POL may include a polarizer and/or a phase retarder of a stretchable film type. The number of the phase retarder and the phase retardation length (λ/4 or λ/2) of the phase retarder may be determined according to the operating principle of the anti-reflection layer POL. In an embodiment, the anti-reflection layer POL may include color filters. The color filters may have a predetermined arrangement. The color filters may be arranged in consideration of the light emitting colors of the light emitting layer EML. In addition, the anti-reflection layer POL may further include a black matrix adjacent to the color filters.

The cover window CW may be disposed on the anti-reflection layer POL. The cover window CW may cover and protect the display panel DP.

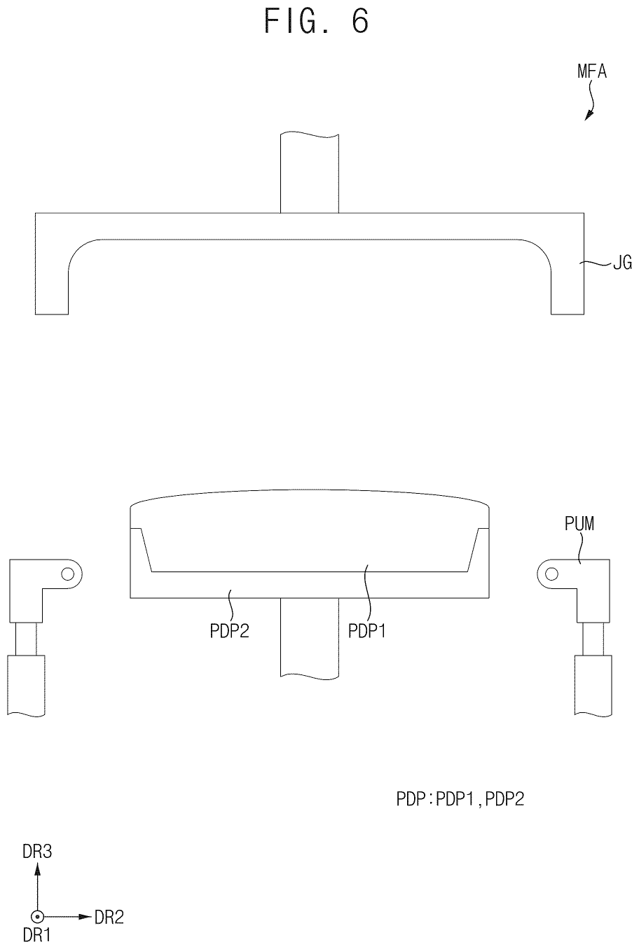

FIG. 6 is a cross-sectional view illustrating an apparatus for manufacturing a display device according to an embodiment of the present disclosure.

Referring to FIG. 6, an apparatus MFA for manufacturing a display device according to an embodiment of the present disclosure may include a pad part PDP, a jig JG, a push member PUM, and a guide film.

The jig JG may be positioned to face the pad part PDP. The cover window (e.g., the cover window CW of FIG. 2) may be disposed inside the jig JG. The jig JG may include a bent portion. In other words, the jig JG may form a concave space to accommodate the cover window. Accordingly, by pressing the cover window against the bent portion, the cover window may be deformed to correspond to a shape of the bent portion.

The pad part PDP may be a member on which the guide film and the display panel (e.g., the display panel DP of FIG. 2) attached to a first surface of the guide film are seated. The pad part PDP may include a first pad part PDP1 and a second pad part PDP2. The first pad part PDP1 may be in contact with the guide film. Specifically, one surface of the first pad part PDP1 which contacts the guide film may include a convex curved surface. That is, a thickness of the first pad part PDP1 may increase from an edge of the first pad part PDP1 to a center of the first pad part PDP1. In this case, the thickness of the first pad part PDP1 may refer to a length of the first pad part PDP1 in the third direction DR3.

The first pad part PDP1 may include an air pump or may be connected to an air pump. Using the air pump, the shape and volume of the first pad part PDP1 may change depending on air pressure. The first pad part PDP1 may include a diaphragm. Accordingly, in the process of attaching the display panel to the cover window, which will be described below, pressure is applied through the first pad part PDP1 to further attach the cover window disposed inside the jig JG to the display panel disposed on the first pad part PDP1.

The second pad part PDP2 may support the first pad part PDP1. The second pad part PDP2 may include a material that has relatively greater rigidity than the first pad part PDP1. The second pad part PDP2 may move along the first direction DR1 and/or the second direction DR2 together with the first pad part PDP1.

The push member PUM may apply an external force to the guide film disposed on the first pad part PDP1. As the external force is applied to the guide film, the guide film may be bent in a direction opposite to the third direction DR3. When the guide film is bent by the external force, the display panel attached to the guide film may also be bent in the direction opposite to the third direction DR3. Accordingly, the display panel may be pre-formed into a shape that matches the shape of the cover window.

The apparatus MFA for manufacturing the display device may include a plurality of push members PUM. For example, as illustrated in FIG. 6, the apparatus MFA may include two push members PUM. However, the present disclosure is not limited thereto. For example, the apparatus MFA may include four push members PUM or six push members PUM spaced apart from each other along the perimeter of the pad part PDP.

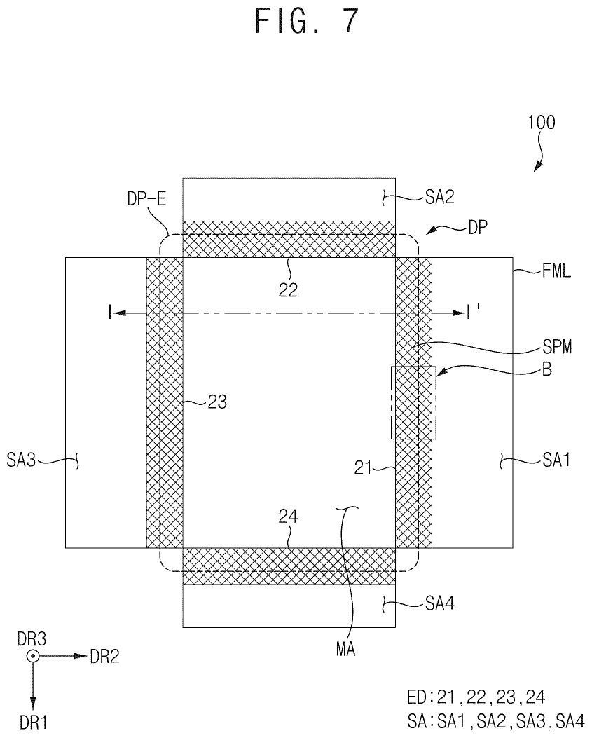

The guide film may be disposed on the pad part PDP. The display panel may be attached to the first surface of the guide film. A second surface of the guide film opposite to the first surface may contact the first pad part PDP1. By the external force applied by the push member PUM, the guide film may be bent together with the display panel so that the display panel is pre-formed into a shape that matches the shape of the cover window. In an embodiment, the guide film may include a base film on which the display panel is disposed and a support member disposed in the base film. A detailed descriptions of this will be described below with reference to FIGS. 7 to 13.

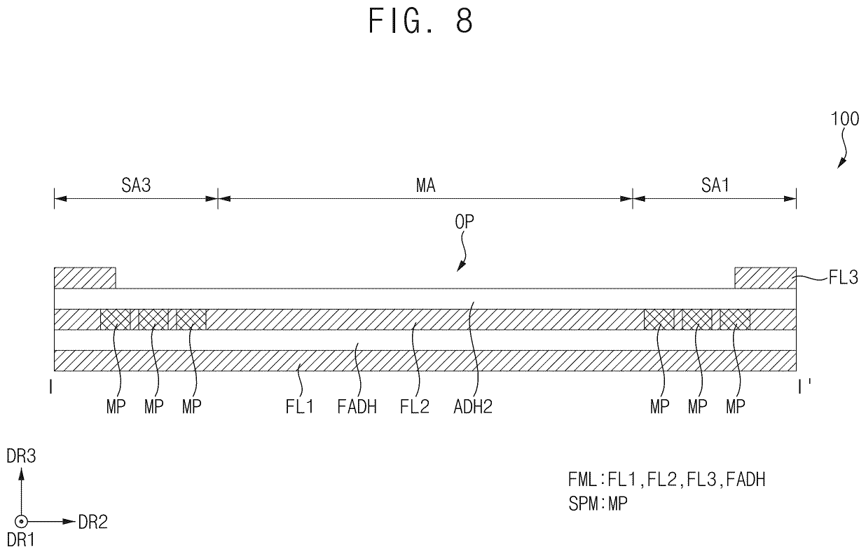

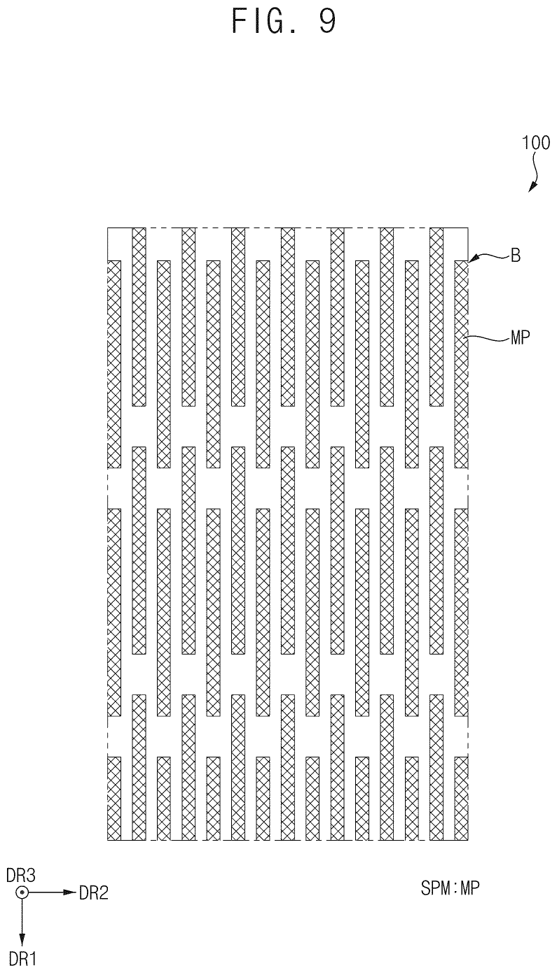

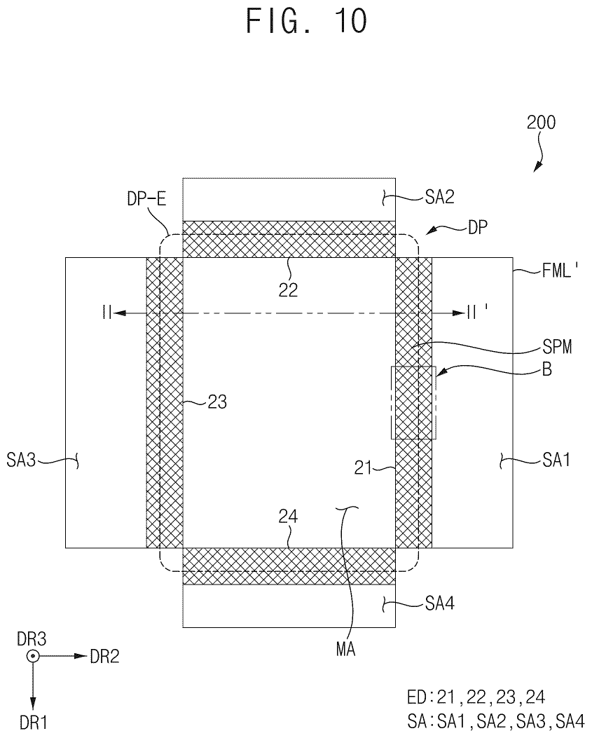

FIG. 7 is a plan view illustrating a guide film according to an embodiment of the present disclosure. FIG. 8 is a cross-sectional view taken along line I-I′ of FIG. 7. FIG. 9 is an enlarged plan view of area ‘B’ of FIG. 7.

Referring to FIGS. 6, 7, 8, and 9, The apparatus MFA for manufacturing the display device according to an embodiment of the present disclosure may include the pad part PDP, the jig JG, the push member PUM, and a guide film 100. The guide film 100 according to an embodiment of the present disclosure may include a base film FML and a support member SPM.

The base film FML may include a main area MA and an auxiliary area SA. When the display panel DP is attached to a first surface of the base film FML, the main area MA of the base film FML may support the display panel DP. An edge ED of the main area MA may include a first side 21, a second side 22, a third side 23, and a fourth side 24. The first side 21 and the third side 23 may face each other and extend in parallel along a straight line extending in the first direction DR1. Each of the second side 22 and the fourth side 24 may contact the first side 21 and the third side 23. The second side 22 and the fourth side 24 may face each other and extend in parallel along a straight line extending in the second direction DR2. In an embodiment, a length of the first side 21 may be greater than a length of the second side 22. That is, the main area MA may have a rectangular shape in a plan view, with the first side 21 as a long side and the second side 22 as a short side. However, the present disclosure is not limited thereto.

When the display panel DP is attached to the first surface of the base film FML, the main area MA may overlap the main display area MDA of FIG. 1. In this case, the first surface of the base film FML may be defined as a surface facing the jig JG.

The auxiliary area SA may contact the edge ED of the main area MA. The auxiliary area SA may extend outward from the edge ED of the main area MA. In the process of bending the display panel DP by applying an external force to the guide film 100, which will be described below, the auxiliary area SA of the base film FML may be bent by the external force.

The auxiliary area SA may include a first auxiliary area SA1, a second auxiliary area SA2, a third auxiliary area SA3, and a fourth auxiliary area SA4. The first auxiliary area SA1 may contact the first side 21 and extend outward from the first side 21. For example, the first auxiliary area SA1 may be connected to the entirety of the first side 21. The second auxiliary area SA2 may contact the second side 22 and extend outward from the second side 22. For example, the second auxiliary area SA2 may be connected to the entirety of the second side 22. The third auxiliary area SA3 may contact the third side 23 and extend outward from the third side 23. For example, the third auxiliary area SA3 may be connected to the entirety of the third side 23. The fourth auxiliary area SA4 may contact the fourth side 24 and extend outward from the fourth side 24. For example, the fourth auxiliary area SA4 may be connected to the entirety of the fourth side 24.

When the display panel DP is attached to the first surface of the base film FML, the auxiliary area SA may overlap the main display area MDA and the side display area SDA of FIG. 1. Specifically, the first auxiliary area SA1 may overlap a portion of the main display area MDA and the first side display area SDA1 of FIG. 1. The second auxiliary area SA2 may overlap a portion of the main display area MDA and the second side display area SDA2 of FIG. 1. The third auxiliary area SA3 may overlap a portion of the main display area MDA and the third side display area SDA3 of FIG. 1. The fourth auxiliary area SA4 may overlap a portion of the main display area MDA and the fourth side display area SDA4 of FIG. 1.

In an embodiment, when the display panel DP is attached to the first surface of the base film FML, the base film FML may not overlap the corner display area (e.g., the corner display area CDA of FIG. 1). However, the present disclosure is not limited thereto.

In an embodiment, the base film FML in the main area MA may include a different material from the base film FML in the auxiliary area SA. For example, the base film FML may include silicon rubber in the main area MA, and the base film FML may include polyethylene terephthalate (PET) in the auxiliary area SA. However, the present disclosure is not limited thereto.

In an embodiment, the base film FML in the main area MA may include the same material as the base film FML in the auxiliary area SA.

The support member SPM may be disposed in the base film FML in the auxiliary area SA. In an embodiment, the support member SPM may be disposed in the base film FML in an area of the auxiliary area SA adjacent to the main area MA. That is, the support member SPM may be disposed in the base film FML in an area of the first auxiliary area SA1 adjacent to the main area MA. The support member SPM may be disposed in the base film FML in an area of the second auxiliary area SA2 adjacent to the main area MA. The support member SPM may be disposed in the base film FML in an area of the third auxiliary area SA3 adjacent to the main area MA. The support member SPM may be disposed in the base film FML in an area of the fourth auxiliary area SA4 adjacent to the main area MA.

When the display panel DP is attached to the first surface of the base film FML, the support member SPM may overlap an edge of the display panel DP in a plan view. For example, the support member SPM may overlap the first side display area, the second side display area, the third side display area, and the fourth side display area in a plan view.

In a process of attaching the display panel DP to the cover window without using the guide film 100, a problem may occur in which bubbles are generated as the cover window is lifted in an area where the cover window is bent due to the shape restoration of components (e.g., the anti-reflection layer POL, the cover panel CPL of FIG. 4) included in the display panel DP. In other words, as the bubbles are generated, a defect may occur in which the display panel DP and the cover window are not smoothly attached to each other.

The guide film 100 according to an embodiment of the present disclosure may include the support member SPM disposed in the base film FML and overlapping an area where the display panel DP and the cover window are bent in a plan view. The rigidity of the support member SPM may be greater than the rigidity of the base film FML. As the support member SPM having relatively high rigidity is disposed in the base film FML, in the process of attaching the display panel DP to the cover window, the components included in the display panel DP may not be restored to their original shape before being attached (i.e., the shape before being bent). That is, the generation of the bubbles due to lifting of the cover window in an area where the cover window is bent may be suppressed. Accordingly, the display panel DP and the cover window may be smoothly attached to each other.

In an embodiment, the support member SPM may include a metal. However, the present disclosure is not limited thereto. For example, the support member SPM may include plastic. The material included in the support member SPM may be determined by considering elongation, tensile strength, etc.

As illustrated in FIG. 8, the base film FML may have a multi-layer structure. In an embodiment, the base film FML may include a plurality of film layers, and at least one of the plurality of film layers may include the support member SPM. For example, the support member SPM may be disposed in at least one of the plurality of film layers. The support member SPM may include a plurality of support patterns MP that are spaced apart from each other. In an embodiment, the base film FML may include a first film layer FL1, a film adhesive layer FADH, a second film layer FL2, and a third film layer FL3. The second adhesive layer ADH2 may be disposed between the second film layer FL2 and the third film layer FL3. The guide film 100 in the first auxiliary area SA1 and the third auxiliary area SA3 may include a structure that is substantially the same as or symmetrical to the guide film 100 in the second auxiliary area SA2 and the fourth auxiliary area SA4. Therefore, hereinafter, the following description will focus on the first auxiliary area SA1 and the third auxiliary area SA3.

The first film layer FL1 may be disposed in the main area MA of the guide film 100 and the auxiliary area SA thereof. For example, the first film layer FL1 may be disposed in the main area MA, the first auxiliary area SA1, and the third auxiliary area SA3. Although not illustrated in FIG. 8, the first film layer FL1 may be disposed in the second auxiliary area SA2 and the fourth auxiliary area SA4. The first film layer FL1 may cover the second surface of the base film FML, which is opposite to the first surface. For example, a lower surface of the first film layer FL1 may correspond to the second surface of the base film FML. The second surface of the base film FML may be defined as a surface that contacts the pad part PDP.

The second film layer FL2 may be disposed on the first film layer FL1 in the main area MA and the auxiliary area SA. For example, the second film layer FL2 may be disposed on the first film layer FL1 in the main area MA, the first auxiliary area SA1, and the third auxiliary area SA3.

A space capable of accommodating the support member SPM is defined in the second film layer FL2, and the support member SPM may be disposed in the space of the second film layer FL2. The support member SPM may include the plurality of support patterns MP that are spaced apart from each other. For example, the support patterns MP may be spaced apart from each other in the second direction DR2. Although not illustrated in FIG. 8, the support patterns MP may be spaced apart from each other in the first direction DR1. In this case, the second film layer FL2 and the support patterns MP may be formed at the same height.

The film adhesive layer FADH may be disposed between the first film layer FL1 and the second film layer FL2. The film adhesive layer FADH may attach the first film layer FL1 and the second film layer FL2. The film adhesive layer FADH may be disposed entirely over the main area MA and the auxiliary area SA.

The third film layer FL3 may be disposed on the second film layer FL2 in the auxiliary area SA. That is, the third film layer FL3 may not be disposed in the main area MA. For example, the third film layer FL3 may overlap a portion of the first auxiliary area SA1 and a portion of the third auxiliary area SA3.

The third film layer FL3 may cover a portion of the first surface of the base film FML. For example, an upper surface of the third film layer FL3 may be a part of the first surface of the base film FML. In addition, the third film layer FL3 may define an opening OP exposing a portion of the second adhesive layer ADH2. The opening OP may overlap the main area MA and a portion of the auxiliary area SA. For example, the opening OP may overlap the main area MA, a portion of the first auxiliary area SA1, and a portion of the third auxiliary area SA3. When the display panel DP is attached to the first surface of the base film FML, the display panel DP may contact the second adhesive layer ADH2 through the opening OP. Accordingly, the display panel DP may be attached to the first surface of the base film FML. In an embodiment, the third film layer FL3 may be omitted.

The second adhesive layer ADH2 may be disposed between the second film layer FL2 and the third film layer FL3. The second adhesive layer ADH2 may attach the second film layer FL2 and the third film layer FL3. In addition, when the display panel DP is attached to the first surface of the base film FML, the second adhesive layer ADH2 may attach the display panel DP and the base film FML. The second adhesive layer ADH2 may be disposed entirely over the main area MA and the auxiliary area SA.

For example, each of the first film layer FL1, the second film layer FL2, and the third film layer FL3 may include silicon rubber, polyethylene terephthalate (PET), etc. However, the present disclosure is not limited thereto.

For example, each of the film adhesive layer FADH and the second adhesive layer ADH2 may include a transparent adhesive such as a pressure sensitive adhesive (PSA) film, an optically clear adhesive (OCA) film, and an optically clear adhesive resin (OCR).

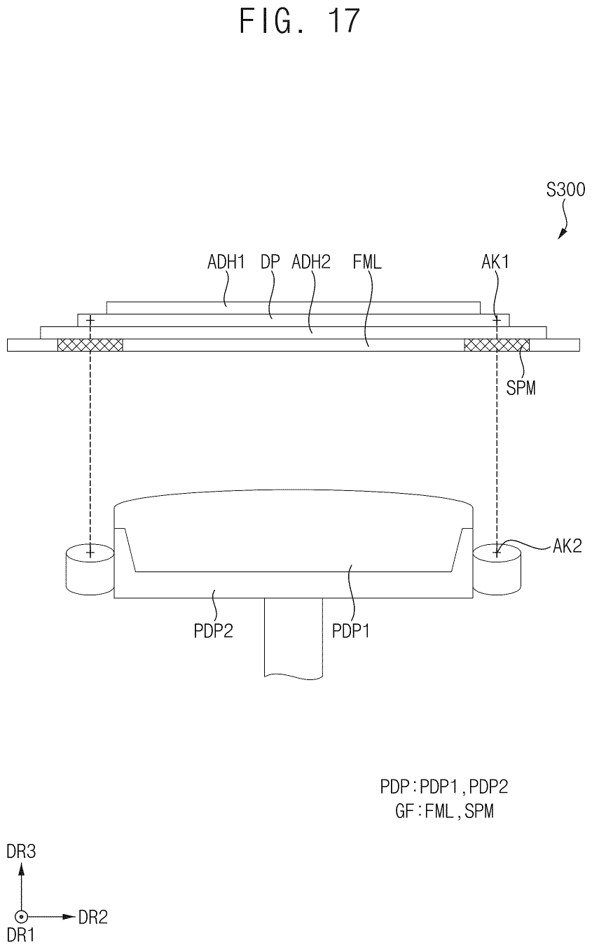

In an embodiment, as illustrated in FIG. 9, the support member SPM may include the support patterns MP that are spaced apart from each other, and the support patterns MP may be arranged in a zigzag shape in a plan view. However, the present disclosure is not limited thereto, and the support patterns MP may be repeatedly arranged along the first direction DR1 and the second direction DR2 in a plan view. In the process of attaching the guide film 100 to a back surface of the display panel DP, which will be described below, the support patterns MP may serve as alignment marks. A detailed description of this will be described below with reference to FIG. 17.

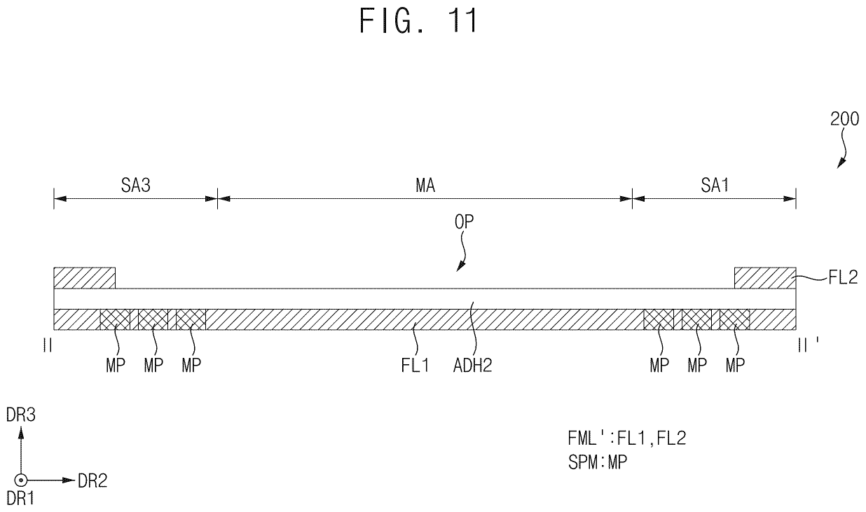

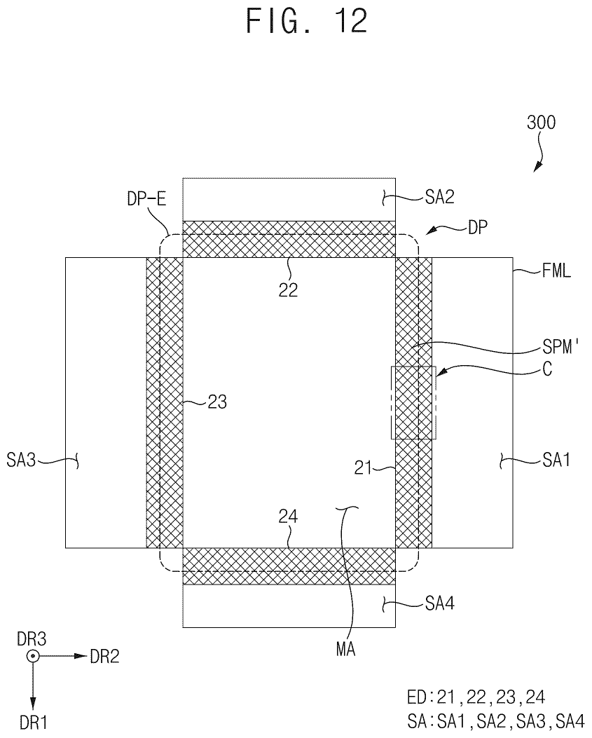

FIG. 10 is a plan view illustrating a guide film according to an embodiment of the present disclosure. FIG. 11 is a cross-sectional view taken along line II-II′ of FIG. 10.

Referring to FIGS. 10 and 11, a guide film 200 according to an embodiment of the present disclosure may include a base film FML′ and the support member SPM.

The guide film 200 may be substantially the same as the guide film 100 as described with reference to FIGS. 7, 8, and 9, except for the stacked structure of the base film FML′. Hereinafter, description overlapping descriptions of the guide film 100 as described with reference to FIGS. 7, 8, and 9 will be omitted or simplified.

As illustrated in FIG. 11, the base film FML′ may have a multi-layer structure. In an embodiment, the base film FML′ may include a first film layer FL1 and a second film layer FL2. The second adhesive layer ADH2 may be disposed between the first film layer FL1 and the second film layer FL2. The display panel DP may be attached to a first surface of the base film FML′.

The first film layer FL1 may be disposed in the main area MA and the auxiliary area SA. The first film layer FL1 may cover a second surface of the base film FML′ that is opposite to the first surface. For example, a lower surface of the first film layer FL1 may correspond to the second surface of the base film FML′. The second surface of the base film FML′ may be defined as a surface that contacts the pad part PDP of FIG. 6.

A space capable of accommodating the support member SPM is defined in the first film layer FL1, and the support member SPM may be disposed in the space of the first film layer FL1. The support member SPM may include a plurality of support patterns MP that are spaced apart from each other. In this case, the first film layer FL1 and the support patterns MP may be formed at the same height. In an embodiment, an upper surface of the first film layer FL1 may be coplanar with upper surfaces of the support patterns MP, and the lower surface of the first film pattern FL1 may be coplanar with lower surfaces of the support patterns MP. In an embodiment, the first film layer FL1 may surround a side surface of each of the support patterns MP and expose upper and lower surfaces of the support patterns MP at an upper surface of the first film layer FL1 and a lower surface thereof, respectively.

The second film layer FL2 may be disposed on the first film layer FL1 in the auxiliary area SA. That is, the second film layer FL2 may not be disposed in the main area MA. The second film layer FL2 may cover a portion of the first surface of the base film FML′. For example, an upper surface of the second film layer FL2 may be a part of the first surface of the base film FML′. In addition, the second film layer FL2 may define an opening OP exposing a portion of the second adhesive layer ADH2. When the display panel DP is attached to the first surface of the base film FML′, the display panel DP may contact the second adhesive layer ADH2 through the opening OP. Accordingly, the display panel DP may be attached to the first surface of the base film FML′. In an embodiment, the second film layer FL2 may be omitted. When the second film layer FL2 is omitted, the base film FML′ may have a single-layer structure.

The second adhesive layer ADH2 may be disposed between the first film layer FL1 and the second film layer FL2. The second adhesive layer ADH2 may attach the first film layer FL1 to the second film layer FL2. In addition, when the display panel DP is attached to the first surface of the base film FML′, the second adhesive layer ADH2 may attach the display panel DP to the base film FML′.

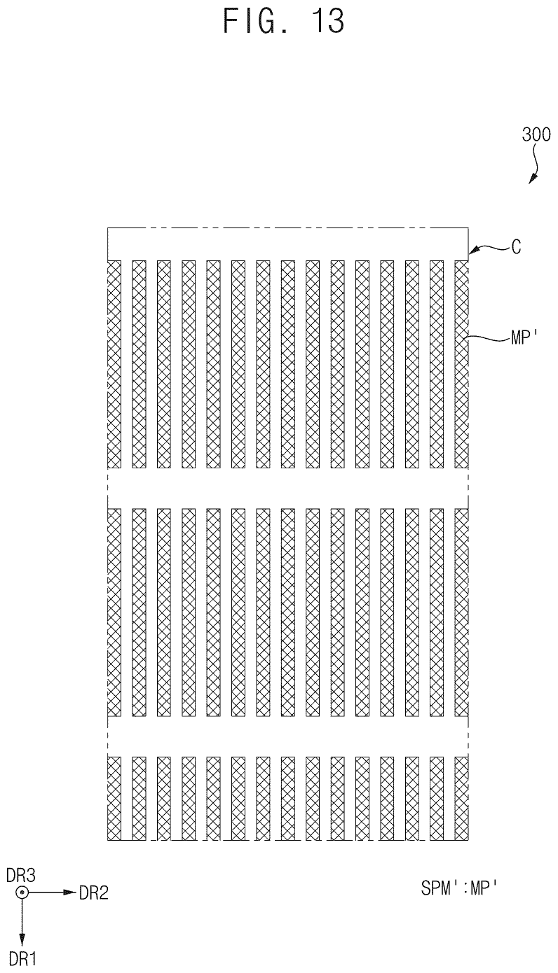

FIG. 12 is a plan view illustrating a guide film according to an embodiment of the present disclosure. FIG. 13 is an enlarged plan view of area ‘C’ of FIG. 12.

Referring to FIGS. 12 and 13, a guide film 300 according to an embodiment of the present disclosure may include the base film FML and a support member SPM′. The support member SPM′ may include support patterns MP′ that are spaced apart from each other.

The guide film 300 may be substantially the same as the guide film 100 as described with reference to FIGS. 7, 8, and 9 except for the shape in which the support patterns MP′ are arranged in a plan view. Hereinafter, description overlapping description of the guide film 100 described with reference to FIGS. 7, 8, and 9 will be omitted or simplified.

In an embodiment, as illustrated in FIG. 13, the support patterns MP′ include a plurality of groups arranged in a line along the first direction DR1 in a plan view, and the plurality of groups are arranged along the second direction DR2. That is, the support patterns MP′ may be arranged in a matrix form along the first direction DR1 and the second direction DR2 in a plan view. However, the present disclosure is not limited thereto. In the process of attaching the guide film 300 to a back surface of the display panel DP, which will be described below, the support patterns MP′ may serve as alignment marks.

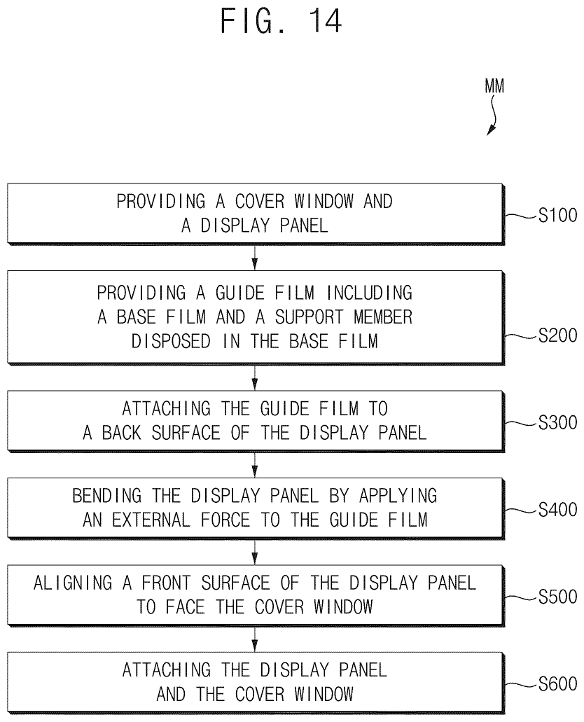

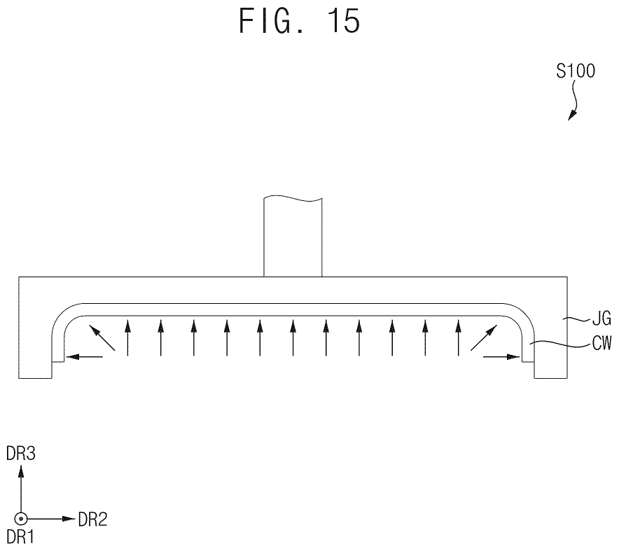

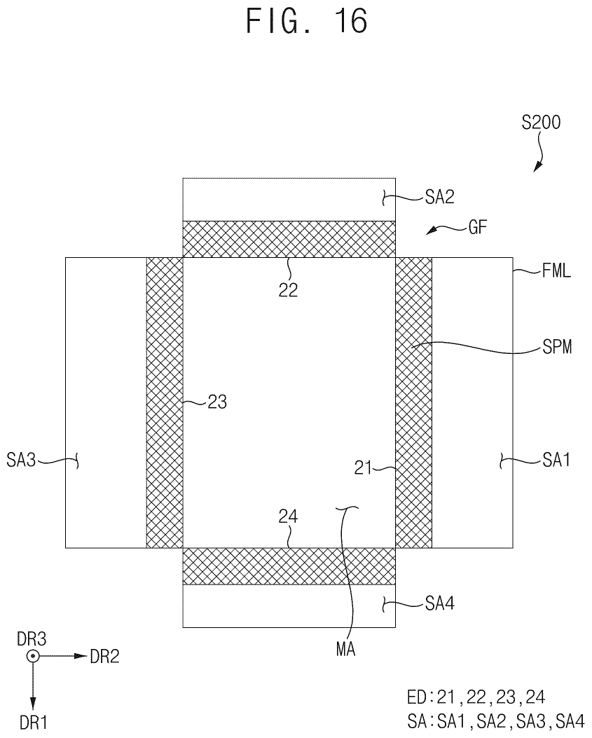

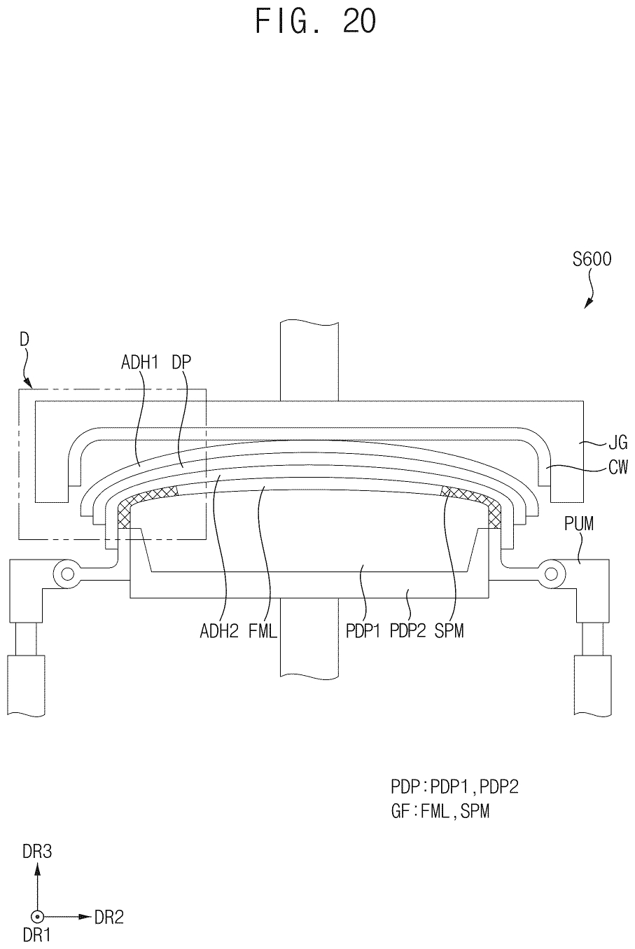

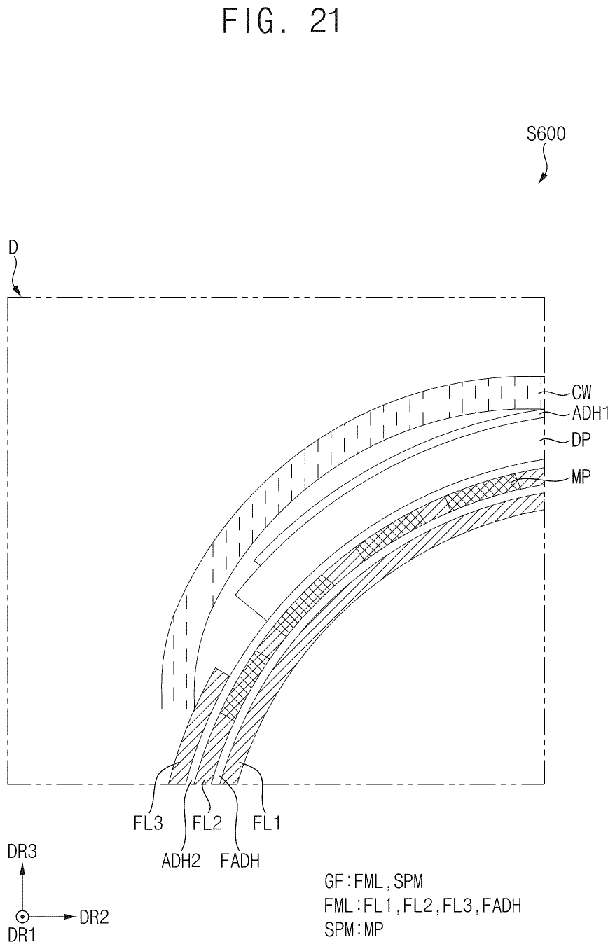

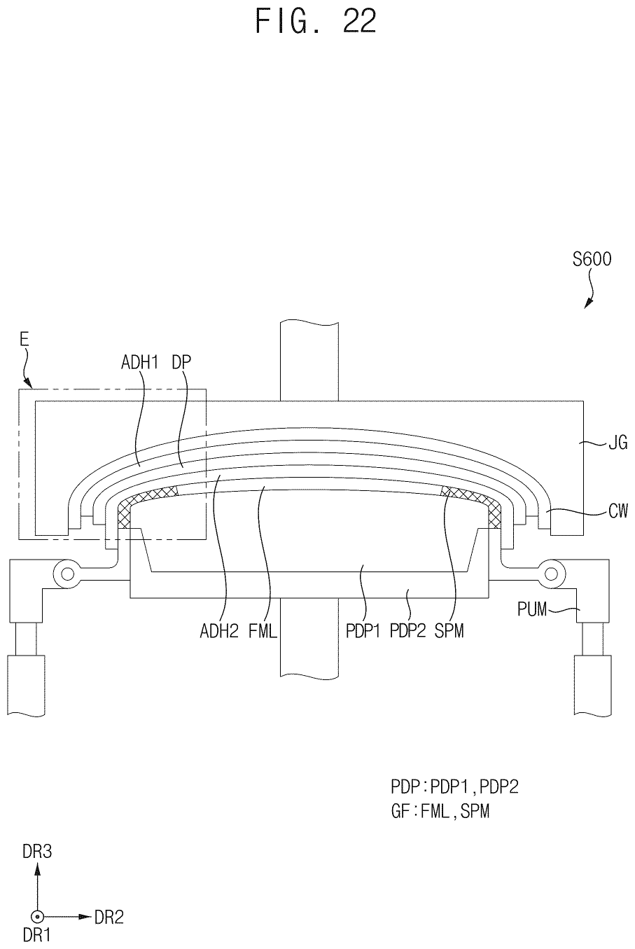

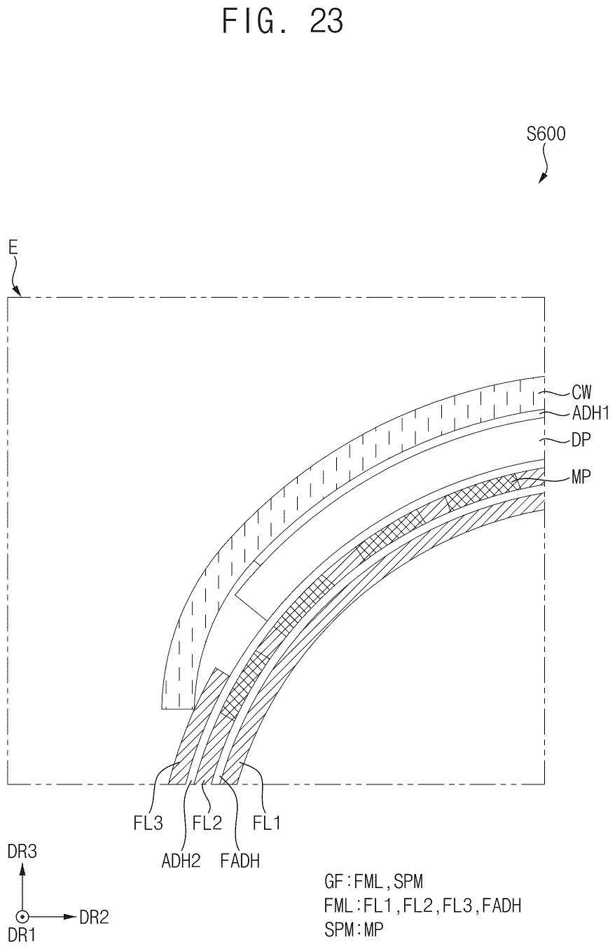

FIG. 14 is a flowchart illustrating a method of manufacturing a display device according to an embodiment of the present disclosure. FIGS. 15, 16, 17, 18, 19, 20, 21, 22, and 23 are views illustrating the method of manufacturing the display device of FIG. 14. For example, FIG. 21 is an enlarged cross-sectional view of area ‘D’ of FIG. 20. FIG. 23 is an enlarged cross-sectional view of area ‘E’ of FIG. 22.

Referring to FIG. 14, a method MM of manufacturing a display device according to an embodiment of the present disclosure may include providing a cover window and a display panel (S100), providing a guide film including a base film and a support member disposed in the base film (S200), attaching the guide film to a back surface of the display panel (S300), bending the display panel by applying an external force to the guide film (S400), aligning a front surface of the display panel to face the cover window (S500), and attaching the display panel and the cover window (S600).

Referring to FIG. 15, a cover window CW may be provided (S100).

The jig JG may include a bent portion. In other words, the jig JG may form a concave space to accommodate the cover window CW. The cover window CW may be disposed on the bent portion of the jig JG. Accordingly, by pressing the cover window CW against the bent portion, the cover window CW may be deformed to correspond a shape of the bent portion.

Although not illustrated in FIG. 15, a display panel may be provided. The display panel may include the substrate SUB, the display layer DPL, the encapsulation layer TFE, the touch sensing layer TSP, the anti-reflection layer POL, and the cover panel CPL of FIG. 4. The first adhesive layer ADH1 of FIG. 4 may be disposed on a front surface of the display panel.

Referring to FIG. 16, a guide film GF including a base film FML and a support member SPM disposed in the base film FML may be provided (S200). The guide film GF as illustrated in FIG. 16 may correspond to any one of the guide film 100 as illustrated in FIGS. 7 to 9, the guide film 200 as illustrated in FIGS. 10 and 11, and the guide film 300 as illustrated in FIGS. 12 and 13. Hereinafter, the description will focus on a case where the guide film GF is the guide film 100 illustrated in FIGS. 7 to 9.

The base film FML may include a main area MA and an auxiliary area SA. In the attaching the display panel to a first surface of the base film FML (S300), which will be described below, the main area MA of the base film FML may support the display panel. The auxiliary area SA may contact an edge ED of the main area MA and extend outward from the edge ED of the main area MA. In the bending the display panel by applying an external force to the guide film GF (S400), which will be described below, the auxiliary area SA of the base film FML may be bent by the external force.

The support member SPM may be disposed in the base film FML in the auxiliary area SA. Specifically, the support member SPM may be disposed in the base film FML in an area of the auxiliary area SA adjacent to the main area MA. In the attaching the display panel to the first surface of the base film FML (S300), the support member SPM may at least partially overlap an edge DP-E of the display panel DP in a plan view (i.e., may overlap at least a portion of the edge DP-E of the display panel DP when viewed in a plan view as shown in FIG. 7). The support member SPM may include the support patterns MP of FIG. 9 that are spaced apart from each other.

The rigidity of the support member SPM may be greater than the rigidity of the base film FML. In an embodiment, the support member SPM may include a metal. Examples of the metal that may be used as the support member SPM may include copper (Cu), aluminum (Al), molybdenum (Mo), titanium (Ti), silver (Ag), platinum (Pt), etc. These may be used alone or in combination with each other. However, the present disclosure is not limited thereto, and the metal that may be used as the support member SPM may be determined by considering elongation, tensile strength, etc.

Referring to FIG. 17, the guide film GF may be attached to the back surface of the display panel DP (S300).

A first adhesive layer ADH1 may be disposed on the front surface of the display panel DP, and a second adhesive layer ADH2 may be disposed on the first surface of the base film FML. The second adhesive layer ADH2 may attach the back surface of the display panel DP to the first surface of the base film FML.

In an embodiment, the display panel DP and the guide film GF may be aligned with each other before the display panel DP and the guide film GF are attached with each other. In this case, in order to align the display panel DP and the guide film GF with each other, a first alignment mark AK1 marked on the display panel DP and the support member SPM included in the guide film GF may be aligned with each other. Specifically, the first alignment mark AK1 and the support patterns may be aligned with each other. For example, a camera disposed under the support member SPM (or disposed on the display panel DP) may measure the first alignment mark AK1 of the display panel DP and the support patterns of the guide film GF. In an embodiment, the camera may be a line scan camera or an area scan camera. Considering a relative position of the first alignment mark AK1 and the support patterns measured by the camera, the first alignment mark AK1 and the support patterns may be aligned with each other.

That is, the support patterns may serve as alignment marks. In an embodiment, the shape and size of the first alignment mark AK1 may correspond to the shape and size of the support patterns at a location corresponding to the first alignment mark AK1. However, the present disclosure is not limited thereto. Accordingly, the alignment accuracy between the display panel DP and the guide film GF may be relatively increased. Specifically, to align the display panel DP and the guide film GF, when aligning the first alignment mark AK1 and the support patterns, the alignment accuracy between the display panel DP and the guide film GF may be relatively increased compared to a case of aligning the first alignment mark AK1 and the edge ED of the main area MA of FIG. 16. After aligning the display panel DP and the guide film GF with each other, the guide film GF may be attached to the back surface of the display panel DP by the second adhesive layer ADH2.

In an embodiment, when the display panel DP is attached to the first surface of the base film FML, the support member SPM may overlap an edge DP-E of the display panel DP when viewed in a plan view. In an embodiment, the support member SPM may at least overlap a portion of the edge DP-E of the display panel PD when viewed in a plan view as shown in FIGS. 7, 10, and 12.

After the back surface of the display panel DP is attached to the first surface of the guide film GF, the guide film GF may be seated on the pad part PDP. Specifically, the first pad part PDP1 may contact a second surface of the guide film GF that is opposite to the first surface. One surface of the first pad part PDP1 that contacts the second surface of the guide film GF may include a convex curved surface. In an embodiment, the entire surface of the first part PDP1 may contact the second surface of the guide film GF, and may be a convex curved surface.

In an embodiment, the guide film GF and the pad part PDP may be aligned with each other before the guide film GF is seated on the pad part PDP. In this case, in order to align the guide film GF and the pad part PDP with each other, a second alignment mark AK2 marked on the pad part PDP may be aligned with the support member SPM included in the guide film GF.

Specifically, the second alignment mark AK2 and the support patterns of the support member SPM may be aligned with each other. For example, a camera disposed under the pad part PDP (or disposed on the guide film GF) may measure the second alignment mark AK2 of the pad part PDP and the support patterns of the guide film GF. Considering a relative position of the second alignment mark AK2 and the support patterns measured by the camera, the second alignment mark AK2 and the support patterns may be aligned with each other. In an embodiment, the shape and size of the second alignment mark AK2 may correspond to the shape and size of the support patterns at a location corresponding to the second alignment mark AK2. However, the present disclosure is not limited thereto.

In an embodiment, in order to align the guide film GF and the pad part PDP with each other, the second alignment mark AK2 marked on the pad part PDP may be aligned with the first alignment mark AK1 marked on the display panel DP.

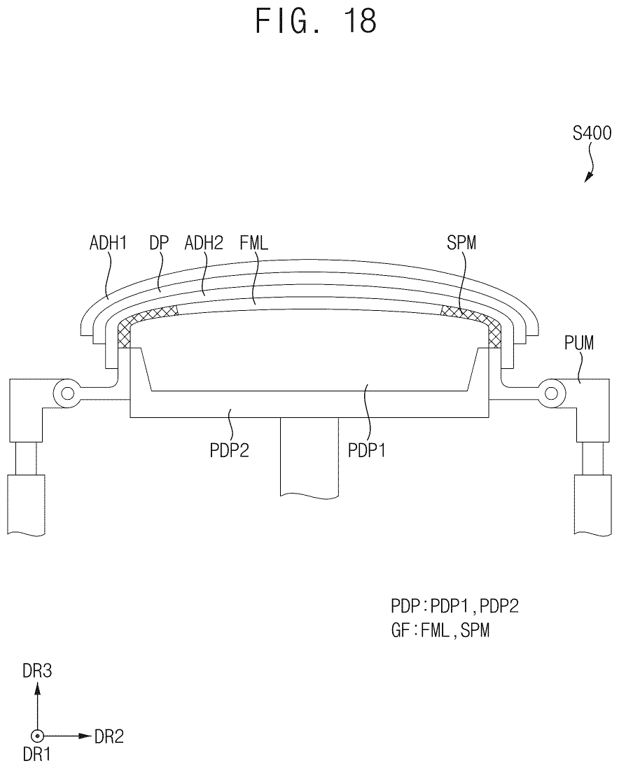

Referring to FIG. 18, the display panel DP may be bent by applying an external force to the guide film GF (S400).

The external force may be applied to the guide film GF seated on the pad part PDP through the push member PUM. As the external force is applied to the guide film GF, the guide film GF may be bent along the convex curved surface of the first pad part PDP1. When the guide film GF is bent by the external force, the display panel DP attached to the guide film GF may also be bent along the convex curved surface of the first pad part PDP1. For example, the opposite sides of the guide film GF may be pushed against the pad part PDP, thereby the shape of the guide film GF being deformed along the convex curved surface of the first pad part PDP1. Accordingly, the display panel DP may be pre-formed into a shape that matches the cover window CW.

In an embodiment, when the guide film GF and the display panel DP are bent by the external force, the support member SPM may at least partially overlap a bent portion of the display panel DP. In an embodiment, the display panel DP bent via the guide film GF may include a curved upper surface and opposite flat side surfaces. The curved upper surface may be connected to the opposite flat side surfaces at the bent portion of the display panel DP. At the bent portion, the curved upper surface and each of the opposite flat side surfaces may be connected with each other.

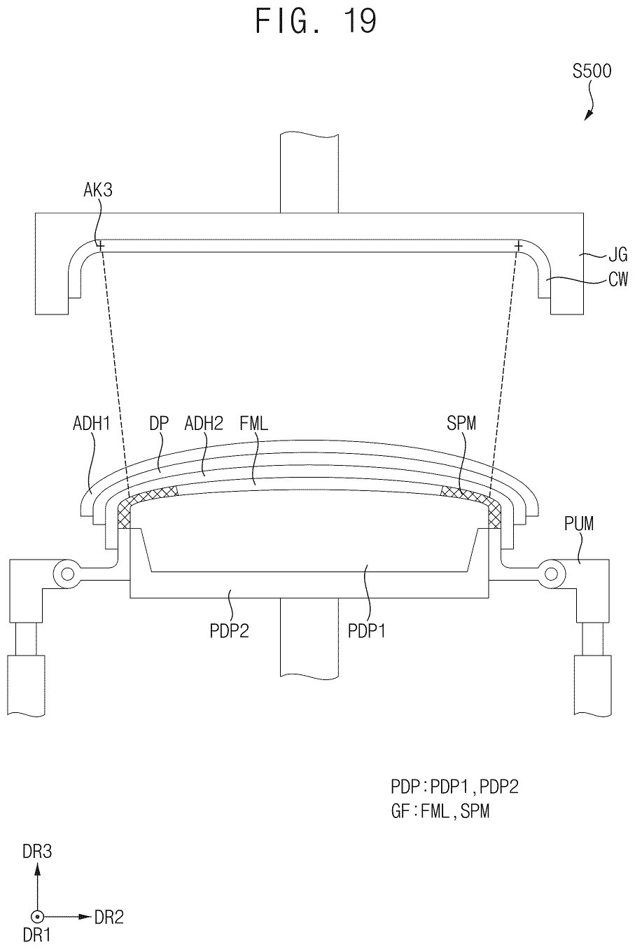

Referring to FIG. 19, the front surface of the display panel DP may be aligned to face the cover window CW (S500).

The front surface of the display panel DP may be positioned to face the cover window CW. In order to align the display panel DP and the cover window CW with each other, a third alignment mark AK3 marked on the cover window CW and the support member SPM included in the guide film GF may be aligned with each other. Specifically, the third alignment mark AK3 and the support patterns of the support member SPM may be aligned with each other. For example, a camera disposed under the guide film GF (or disposed on the cover window CW) may measure the third alignment mark AK3 of the cover window CW and the support patterns of the guide film GF. Considering a relative position of the third alignment mark AK3 and the support patterns measured by the camera, the third alignment mark AK3 and the support patterns may be aligned with each other. In an embodiment, the shape and size of the third alignment mark AK3 may correspond to the shape and size of the support patterns at a location corresponding to the third alignment mark AK3. However, the present disclosure is not limited thereto. In order to align the display panel DP and the cover window CW with each other, the third alignment mark AK3 marked on the cover window CW and the first alignment mark AK1 marked on the display panel DP may be aligned with each other.

Referring to FIGS. 20, 21, 22, and 23, the display panel DP and the cover window CW may be attached with each other (S600). That is, the pad part PDP and the jig JG may move to be adjacent to each other, so that the display panel DP and the cover window CW may be attached with each other.

As illustrated in FIGS. 20 and 21, a central portion of the display panel DP (e.g., the main display area MDA of FIG. 1) may contact the cover window CW first. In other words, an area of the display panel DP that has a flat surface (i.e., an area that is not bent) may contact the cover window CW first. Accordingly, the area of the display panel DP having a flat surface may be first attached to the cover window CW by the first adhesive layer ADH1. In an embodiment, the display panel DP bent via the guide film GF may include a curved upper surface and opposite flat side surfaces. The curved upper surface may be connected to the opposite flat side surfaces. The first adhesive layer ADH1 may be disposed on the entirety of the curved upper surface and at least portions of the opposite flat side surfaces. In the process of the attaching the display panel DP to the cover window CW, the cover window CW may contact an uppermost portion of the curved upper surface, and then the contact area between the cover window CW and the display panel DP may propagate towards the opposite flat side surfaces.

As illustrated in FIGS. 22 and 23, as the pad part PDP and the jig JG are pressed against each other, the display panel DP may sequentially contact the cover window CW from the central portion to a bent portion of the display panel DP.

The first pad part PDP1 may include an air pump or be connected to an air pump. Using the air pump, the shape and volume of the first pad part PDP1 may change depending on air pressure. The first pad part PDP1 may include a diaphragm. Accordingly, the display panel DP and the cover window CW may be further attached by applying pressure through the first pad part PDP1.

The support member SPM may include the support patterns MP that are spaced apart from each other. The support patterns MP may be disposed in the base film FML. For example, the support patterns MP may be disposed in the second film layer FL2 of the base film FML.

The support member SPM may at least partially overlap the bent portion of the display panel DP in a plan view. In other words, the support patterns MP may at least partially overlap the bent portion of the display panel DP in a plan view. As the support patterns MP with relatively high rigidity are disposed in the base film FML so as to overlap the bent portion of the display panel DP in a plan view, in the attaching the display panel DP and the cover window CW (S600), the components (e.g., the anti-reflection layer POL, the cover panel CPL of FIG. 4) included in the display panel DP may not be restored to their original shapes before being bent. That is, the generation of bubbles due to lifting of the cover window CW in an area where the cover window CW is bent may be reduced.

After the display panel DP and the cover window CW are attached with each other, the guide film GF may be removed.

In an embodiment, the second adhesive layer ADH2 that attaches the guide film GF to the display panel DP may include a photo initiator. For example, the second adhesive layer ADH2 may include an ultraviolet ray adhesive sheet. In order to remove the guide film GF, the ultraviolet ray may be irradiated to the second adhesive layer ADH2. Due to the ultraviolet ray, the adhesive strength of the second adhesive layer ADH2 may be weakened. Accordingly, the display panel DP may be separated from the second adhesive layer ADH2, and the guide film GF may be removed from the display panel DP.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A guide film comprising:
a base film including a main area, which includes a first side extending in a first direction and a second side contacting the first side and extending in a second direction crossing the first direction, a first auxiliary area contacting the first side, and a second auxiliary area contacting the second side; and
a support member disposed in the first auxiliary area and the second auxiliary area of the base film and including a metal.

2. The guide film of claim 1,
wherein the support member includes a plurality of support patterns spaced apart from each other.

3. The guide film of claim 2,
wherein the plurality of support patterns are arranged in a zigzag shape in a plan view.

4. The guide film of claim 2,
wherein the plurality of support patterns include a plurality of groups, each of the plurality of groups including at least two support patterns arranged in a straight line extending along the first direction in a plan view, and
wherein the plurality of groups are arranged along the second direction.

5. The guide film of claim 1,
wherein the base film includes a plurality of film layers, and
wherein the support member is disposed in at least one of the plurality of film layers.

6. The guide film of claim 1,
wherein a rigidity of the support member is greater than a rigidity of the base film.

7. The guide film of claim 1,
wherein the main area of the base film includes a different material from each of the first auxiliary area and the second auxiliary area of the base film.

8. An apparatus for manufacturing a display device, the apparatus comprising:
a guide film on which a display panel is disposed;
a jig on which a cover window is disposed; and
a pad part on which the display panel and the guide film are disposed, the pad part facing the jig,
wherein the guide film comprises:
a base film on which the display panel is disposed; and
a support member disposed in the base film, overlapping at least a portion of an edge of the display panel in a plan view, and including a metal.

9. The apparatus of claim 8,
wherein the support member includes a plurality of support patterns spaced apart from each other.

10. The apparatus of claim 9,
wherein the plurality of support patterns are arranged in a zigzag shape in a plan view.

11. The apparatus of claim 9,
wherein the plurality of support patterns include a plurality of groups, each of the plurality of groups including at least two support patterns arranged in a straight line extending along a first direction in a plan view, and
wherein the plurality of groups are arranged along a second direction crossing the first direction.

12. The apparatus of claim 8,
wherein a rigidity of the support member is greater than a rigidity of the base film.

13. A method for manufacturing a display device, the method comprising:
attaching a guide film to a back surface of a display panel, wherein the guide film includes a base film and a support member disposed in the base film, wherein the support member includes a metal, and wherein the support member overlaps at least a portion of an edge of the display panel in a plan view;
bending the display panel by applying an external force to the guide film;
aligning a front surface of the display panel to face a cover window; and
attaching the display panel to the cover window.

14. The method of claim 13,
wherein in the bending the display panel, the support member at least partially overlaps a bent portion of the display panel.

15. The method of claim 13,
wherein the support member includes a plurality of support patterns spaced apart from each other.

16. The method of claim 15,
wherein the attaching the guide film to the back surface of the display panel includes aligning the display panel and the guide film with each other, and
wherein the aligning the display panel and the guide film each other includes aligning a first alignment mark marked on the display panel to the plurality of support patterns of the guide film.

17. The method of claim 15,
wherein the aligning the front surface of the display panel to the cover window includes aligning a second alignment mark marked on the cover window to the plurality of support patterns.

18. The method of claim 15,
wherein the plurality of support patterns are arranged in a zigzag shape in a plan view.

19. The method of claim 15,
wherein the plurality of support patterns include a plurality of groups, each of the plurality of groups including at least two support patterns arranged in a straight line extending along a first direction in a plan view, and
the plurality of groups are arranged along a second direction crossing the first direction.

20. The method of claim 13,
wherein a rigidity of the support member is greater than a rigidity of the base film.
